(19) United States
(12) Patent Application Publication
(10) Pub. No.: US 2026/0178361 A1
(43) Pub. Date: Jun. 25, 2026

(54) METHOD AND SYSTEM FOR COMPREHENSIVE SIMULATION FRAMEWORK

(71) Applicant: Marvell Asia Pte Ltd, Singapore (SG)

(72) Inventors: Ranjeeth Siddakatte, Whitby (CA); Michal Kalderon, Ramat Hasharon (IL); Senad Durakovic, Palo Alto, CA (US); Ulf Hanebutte, Gig Harbor, WA (US); Taif Anjum, North York, Ontario (CA)

(21) Appl. No.: 19/376,835

(22) Filed: Oct. 31, 2025

Related U.S. Application Data
(60) Provisional application No. 63/737,309, filed on Dec. 20, 2024.
(60) Provisional application No. 63/737,347, filed on Dec. 20, 2024.
(60) Provisional application No. 63/822,831, filed on Jun. 12, 2025.

(51) Int. Cl. G06F 9/455; G06F 9/445

(52) U.S. Cl. CPC G06F 9/455; G06F 9/44505

(57) ABSTRACT

A system includes a trace generator module, simulators, a selector module, and an agentic AI module (analytical/decision making/execution agents). The trace generator module receives a workload data and generates a trace data. The selector module receives configuration data associated with another system to be simulated and selects a simulator to a run simulation. The simulator generates a simulation data. The analytical agent analyzes the simulation data to generate actionable insights. The decision making agent receives the actionable insights and generates recommendation associated with one or more modification to be made.

### CROSS-REFERENCE TO RELATED APPLICATIONS

This application is a U.S. Nonprovisional application that claims the benefit and priority to the U.S. Provisional Application No. 63/737,309 that was filed on Dec. 20, 2024, which is incorporated herein by reference in its entirety.

This application is a U.S. Nonprovisional application that claims the benefit and priority to the U.S. Provisional Application No. 63/737,347 that was filed on Dec. 20, 2024, which is incorporated herein by reference in its entirety.

This application is a U.S. Nonprovisional application that claims the benefit and priority to the U.S. Provisional Application No. 63/822,831 that was filed on Jun. 12, 2025, which is incorporated herein by reference in its entirety.

### BACKGROUND

Use of artificial intelligence (AI) has increased substantially and touches every facet of daily life. Increasing use of AI has also resulted in an increase in size and complexity of workloads, e.g., for AI training, for inference, etc. There has been an increased need of computational resources, e.g., data centers, etc., to address the increase in size and complexity of workloads. Typically, increase in computational complexity and workload should be accompanied with high bandwidth and/or low latency (from both processing standpoint as well as communication standpoint) across a number of different compute nodes that may work parallel to one another to process data in a timely fashion. However, increasing the number of compute resources, increasing the number of compute nodes, increasing the amount of memory, increasing the amount of processing power, increasing the bandwidth, reducing the latency for communication and processing, etc., is expensive. Traditional simulations have been used by system architects to plan and configure the existing computational resources, e.g., existing data centers, or plan for future computational resources in order to maximize utilization and reduce cost while attempting to address the increased in size and complexity of workloads.

Traditional simulation frameworks include a number of different individual simulations where each simulation may be focused on workloads and may use algorithmic modeling when at scale. Unfortunately, traditional simulations provide plugins that simulate performance of hardware components, e.g., network interface card (NIC), compute nodes and switches, etc., associated with a workload generically and functionally (i.e., functionally oriented) without the ability to replace one hardware component (with one set of capabilities) with a different hardware component (with a different set of capabilities) and to compare the performance based on the simulation based on that change. It is appreciated that in some embodiments, replacing one hardware component with one set of capabilities with another hardware component with another set of capabilities may have the same functionality or may have different functionality from one another. As such, hardware specific capabilities associated with use of different hardware components is absent from simulation even though that information may have a major impact on the system and its performance, bandwidth, latency, complexity, etc.

Additionally, simulations are typically user driven with some level of automation, algorithmic optimizations, and support for scripting to simplify the process. Unfortunately, these simulation efforts provide performance metrics for a specific configuration instead of providing optimal configuration for a given desired performance.

Moreover, simulations are typically analyzed by the system architect in order to make decisions on modifications to be made to improve performance, e.g., increase utilization, reduce latency, increase bandwidth, etc. This manual process is sub-optimal and unfortunately is point-wise optimization for specific conditions. This traditional and manual process is not only inefficient by being manual with some level of automation for simulation runs but also suffers from additional inefficiencies by requiring different configurations to be tried and for the performance to be manually analyzed, which are one-shot processes that require human analysis and intervention to re-run the tests with new configurations or after troubleshooting issues.

The foregoing examples of the related art and limitations related therewith are intended to be illustrative and not exclusive. Other limitations of the related art will become apparent upon a reading of the specification and a study of the drawings.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts an example of a simulation environment with hardware specific configuration for simulating workload data according to one aspect of the present embodiments.

FIG. 2A depicts an example of a workload data according to one aspect of the present embodiments.

FIG. 2B depicts an example of a configuration data according to one aspect of the present embodiments.

FIG. 2C depicts an example of a topology generated by the simulation environment according to one aspect of the present embodiments.

FIG. 2D depicts an example of a network generated as part of the simulation environment according to one aspect of the present embodiments.

FIG. 2E depicts an example of simulation data according to one aspect of the present embodiments.

FIG. 3A depicts an example of simulation data analysis according to one aspect of the present embodiments.

FIG. 3B depicts an example of simulation rendered according to one aspect of the present embodiments.

FIG. 4A depicts an example of a simulation environment with agentic AI during one simulation iteration to optimize performance according to one aspect of the present embodiments.

FIG. 4B depicts an example of a simulation environment with agentic AI during another simulation iteration to optimize performance according to one aspect of the present embodiments.

FIG. 5 depicts an illustrative flow diagram to support simulation environment based on hardware capabilities for specific hardware capabilities according to one aspect of the present embodiments.

FIG. 6 depicts an illustrative flow diagram to support simulation environment coupled with an agentic AI according to one aspect of the present embodiments.

FIG. 7 depicts an illustrative flow diagram to support simulation environment coupled with a plurality of agentic Als according to one aspect of the present embodiments.

FIG. 8 is a block diagram illustrating an example of a computing system/device used to support the simulation environment and/or agentic AI according to one aspect of the present embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Before various embodiments are described in greater detail, it should be understood that the embodiments are not limiting, as elements in such embodiments may vary. It should likewise be understood that a particular embodiment described and/or illustrated herein has elements which may be readily separated from the particular embodiment and optionally combined with any of several other embodiments or substituted for elements in any of several other embodiments described herein. It should also be understood that the terminology used herein is for the purpose of describing the certain concepts, and the terminology is not intended to be limiting. Unless defined otherwise, all technical and scientific terms used herein have the same meaning as commonly understood in the art to which the embodiments pertain.

A need has arisen to provide a simulation framework that is modular and that uses specific hardware components with specific hardware capabilities in addition to the generic and functional aspects to simulate performance associated with a workload. Hardware specific capabilities may be generally referred to as hardware attributes and may include one or more of processing speed (clock speed), memory capabilities, number of ports, bandwidth, throughput, number of parallel processing threads, number of processing elements, number of local memories, number of cache units, persistent storage types, memory channels, input/output and connectivity capabilities, bus interfaces, networking, peripheral support, input/output bandwidth, instruction sets, AI accelerators, parallel processing, thermal design power, thermal management systems, dynamic voltage and frequency scaling, battery capacity, trusted platform module, error correction code (ECC) memory, hardware random number generator, secure boot and firmware validation mechanisms, virtualization extensions, cryptographic accelerators, signal processors such as digital signal processor (DSP), machine learning (ML) accelerators, etc.

As such, a more accurate simulation is provided and additional insights may be gained into specific system configuration based on hardware capabilities, thereby enabling additional parameters to be adjusted, e.g., by replacing one hardware component in the simulation with another (e.g., by different hardware components), to improve performance and further to compare simulation result performance for one hardware component with another (based on their different capabilities and different hardware attributes). The simulation may be used to modify one or more aspect of the system, e.g., scale up, scale out, replace one hardware component (with one set of capabilities) with a different hardware component (with another set of capabilities), addition/removal of nodes/components, etc., to improve performance, e.g., increase utilization, reduce latency associated with communication or processing, increase bandwidth, reduce bottleneck associated with memory access or data movement, etc. Optimization of the system may result in a different system topology. It is appreciated that simulations of the system according to some embodiments enable the workload and software stack to be evaluated, e.g., by changing parallelization strategies. In one nonlimiting example, a new input (e.g., trace) may be provided to the simulator to reflect a change to the workload and/or software. In one nonlimiting example, the simulation according to some embodiments may provide insights into resiliency of the hardware components (e.g., network link, network switch, etc.), their failure and/or degradation as well as allowing optimization of network by reducing network congestions based on the insights gains from the simulation environment.

The modular and specific hardware capabilities simulation provided by the new simulation network enables additional insights to be gained, e.g., specific system configuration based on different hardware capabilities. Comprehensive comparison between different hardware components based on their capabilities offer additional insight to optimize the system at scale. It is appreciated that the new simulation network may be used to capture additional data, e.g., logfiles, intermediate data, etc., thereby making the simulation and its analysis more AI friendly, which can subsequently be used to train and to be used in an agentic AI. It is appreciated that agentic AI generally refers to an AI system that exhibits agency, e.g., taking initiative, making decisions autonomously, performing actions to achieve goals with minimal to no human input, etc., to adapt to new information over time.

Although the diagrams depict components as functionally separate, such depiction is merely for illustrative purposes. It will be apparent that the components portrayed in this figure can be arbitrarily combined or divided into separate software, firmware and/or hardware components. Furthermore, it will also be apparent that such components, regardless of how they are combined or divided, can execute on the same host or multiple hosts, and wherein the multiple hosts can be connected by one or more networks. Each of the engines in the following figures is a dedicated hardware block/component including one or more microprocessors and on-chip memory units storing software instructions programmed for providing a comprehensive simulation environment and one or more agentic AIs to autonomously decide on parameters to be modified in order to optimize the system. When the software instructions are executed by the microprocessors, each of the hardware components becomes a special purposed hardware component for practicing certain machine learning functions as discussed in detail below. In some embodiments, the system described below may be implemented as a single chip, e.g., a system-on-chip (SOC).

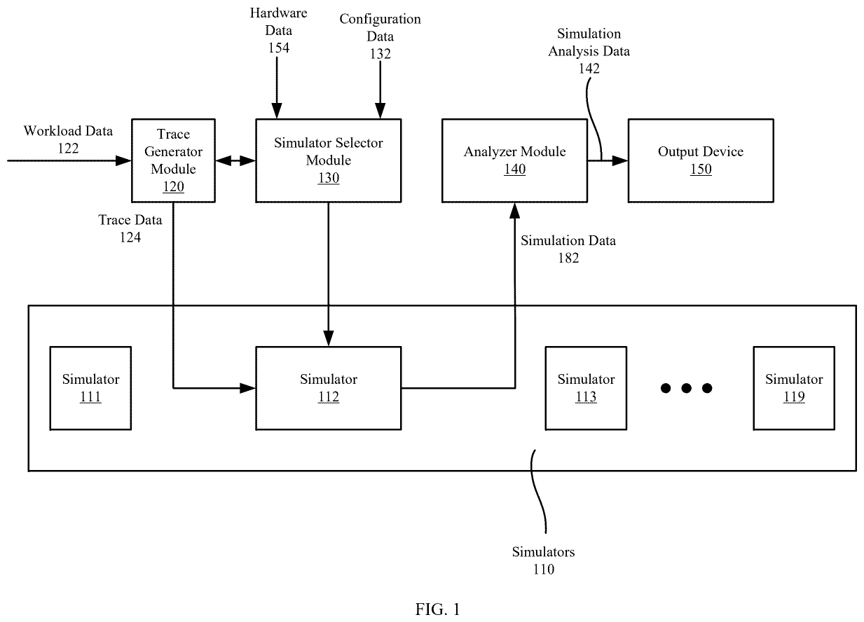

FIG. 1 depicts an example of a simulation environment with hardware specific configuration for simulating workload data according to one aspect of the present embodiments. The simulation environment may include simulators 110 (e.g., simulators 111-119), a trace generator module 120, a simulator selector module 130, an analyzer module 140, and an output device 150. The simulation framework of FIG. 1 is modular and uses specific hardware components (with a set of hardware capabilities) in addition to the generic and functional aspects to simulate performance associated with a workload. The simulators 110 may include one or more simulators, e.g., simulators 111-119. It is appreciated that the number of simulators within the simulators 110 is for illustration purposes and should not be construed as limiting the scope of the embodiments. It is appreciated that each simulator within the simulators 110 may be directed to one aspect of the simulation, e.g., computer system and networking simulations, AI and ML simulations, processor and microarchitecture simulations, memory and storage simulations, network and communication simulation, system-level simulations, thermal and power simulations, reliability and fault tolerance simulations, etc. It is appreciated that the embodiments throughout this application are described with respect to simulation related to data centers for illustrative purposes but that should not be construed as limiting the scope of the embodiments.

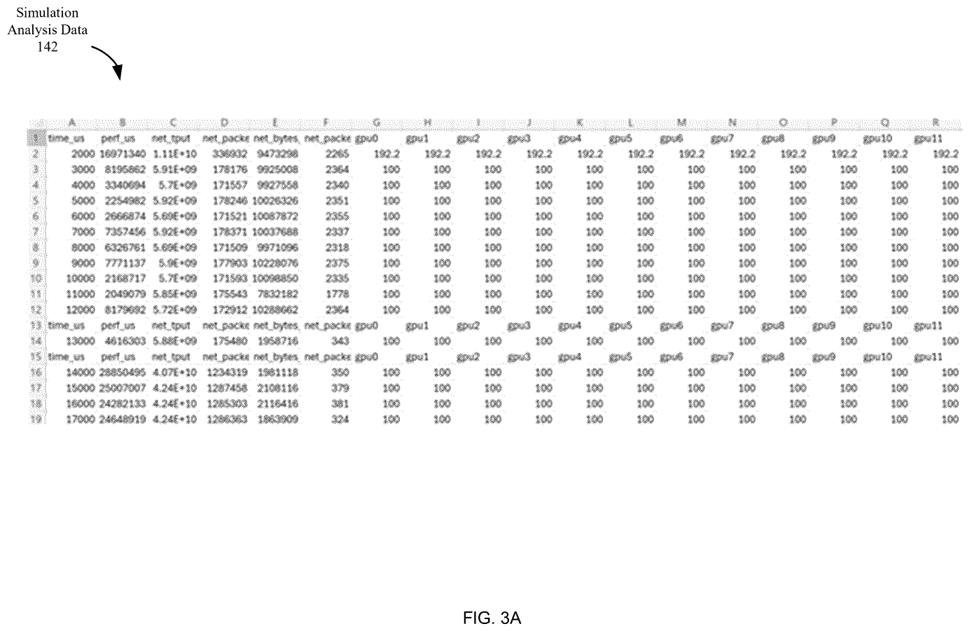

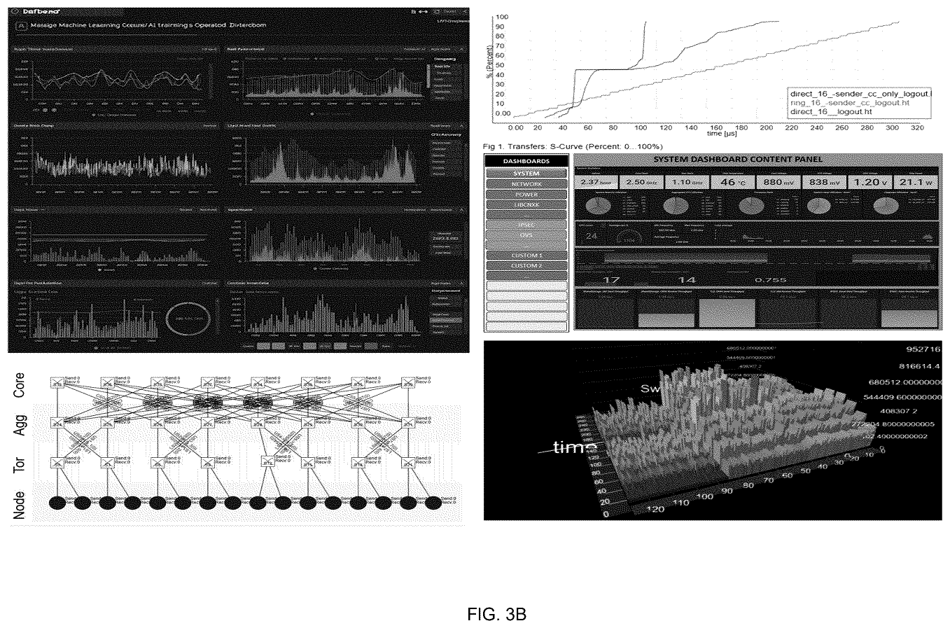

In one nonlimiting example, the trace generator module 120 may receive the workload data 122 and may generate a trace data 124 (described in greater detail below). The trace data 124 along with hardware data 154 and/or configuration data 132 may be provided to the simulator selector module 130. The hardware data 154 and the configuration data 132 are described later in greater detail. The simulator selector module 130 may select one or more simulators from a selection of simulators 110. For example, simulator 112 may be selected based on the received data. The simulator 112 may generate a topology based on the received information, e.g., hardware data 154, configuration data 132, workload data 122, trace data 124, etc. It is appreciated that the simulator 112 may perform simulation based on one or more of the workload data 122 and the trace data 124 using the generated topology. The simulation data 182 may be generated and transmitted to the analyzer module 140 (which may be part of the simulator 112 but shown separate here for illustrative purposes). The analyzer module 140 may parse the simulation data 182, analyze the parsed data, and export the analysis (with the parsed data or subset thereof) as simulation analysis data 142 to the output device 150, e.g., a display. In one nonlimiting example, the simulation analysis data 142 may include individual flow completion times for a collective (transfers: S-curve) and queue occupancies of a switch over time given a 3D graph. Another nonlimiting example of the simulation analysis data 142 includes average GPU utilization of an individual GPU or all GPUs in the system and may further include statistical information, e.g., clock speed, cycles per instructions, instructions per cycle, instructions per second, millions of instructions per seconds (MIPS) or floating point operations per second (FLOPS), pipeline depth/width, branch prediction accuracy, cache hit/miss rates, cache latency, thread usage, idle time, memory latency, cache bandwidth, memory bandwidth, ECC error count, etc. An example representation of the simulation analysis data 142 is shown in FIG. 3B for illustration purposes. It is appreciated that hardware specific data is being received as hardware data 154, thereby providing more insight that can be used to optimize the performance of the system as a whole.

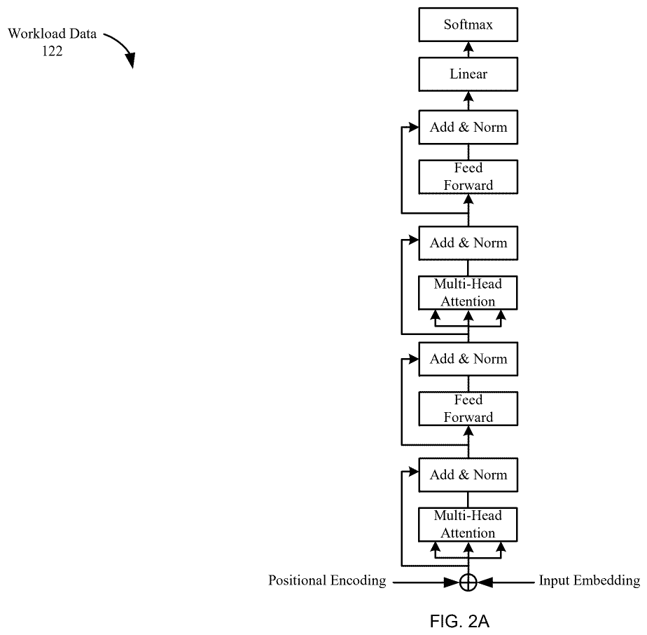

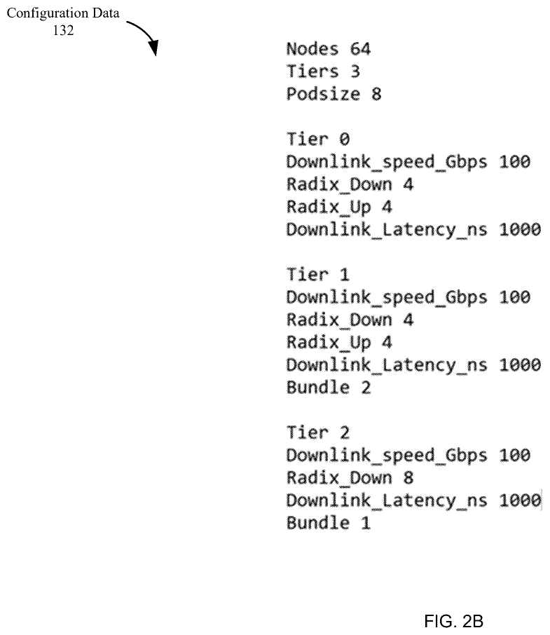

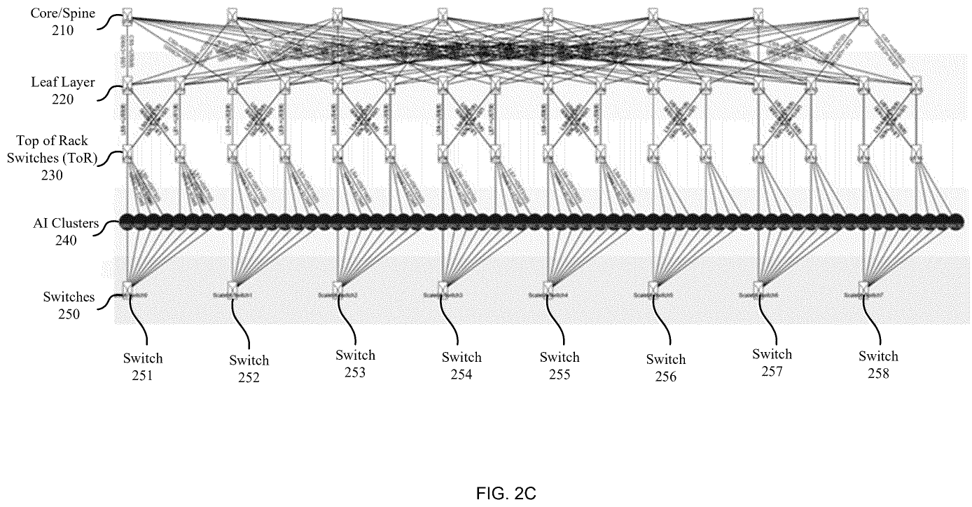

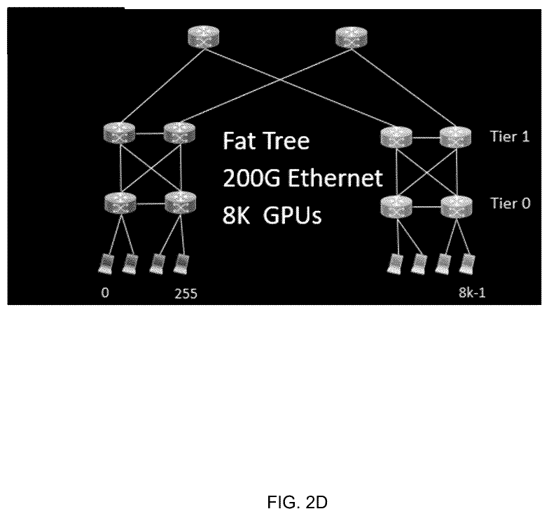

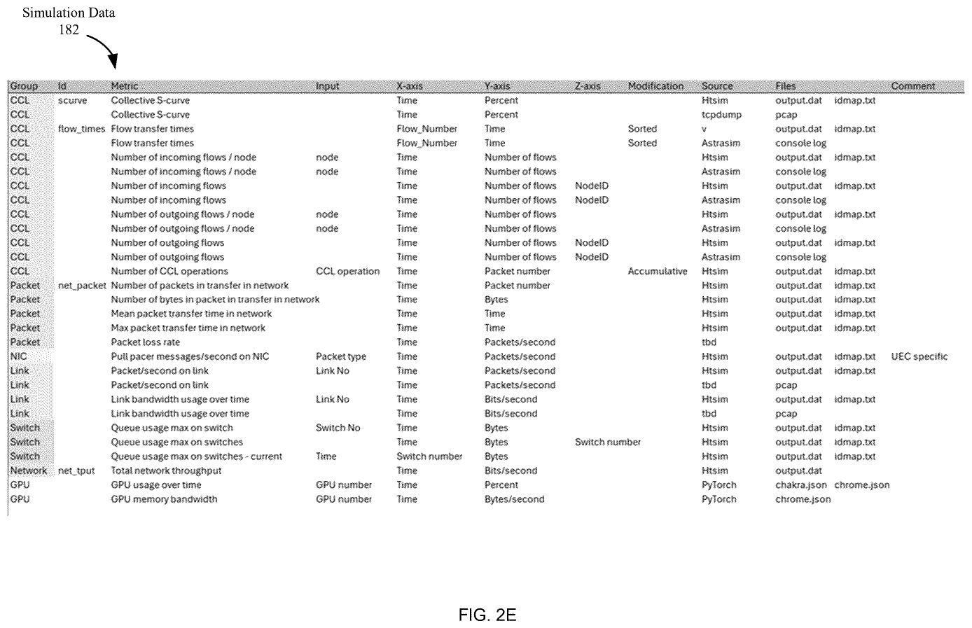

In one nonlimiting example, the trace generator module 120 may generate a trace data 124 based on a workload 122 (e.g., set of tasks, operations, requests, etc.). A nonlimiting example of a workload 122 may be a number of different large language models (LLM) with 1 billion parameters, or 100 billion parameters, etc. An example of a workload 122 is shown in FIG. 2A, which may be derived from Llama-2 with 18 million parameters with input embedding and positional encoding followed 2 transformer layers (with add and norm, feed forward, add and norm, and multi-head attention), linear, and then a softmax operation. In one nonlimiting example, the workload 122 may be defined in PyTorch that support parallelization strategies or may be given as a single collective primitive or a set of collective communication primitives such as AllReduce Scatter or AllToAll. The trace data 124 may be a record of execution or behavior of the system, program, or data flow (described in greater detail below). The trace data 124 may be a file in a given format, e.g., JavaScript Object Notation (JSON) format. In one nonlimiting example, the trace data 124 may be a LLM model trace file that captures the LLM's training behavior for a number of iterations. The trace generator module 120 may use a profiler such as PyTorch profiler (used to analyze and optimize the performance of the model during training and inference) to generate trace data associated with a workload (e.g., model such as Llama). In one nonlimiting example, the trace data 124 may be generated for any mode, e.g., an ML model, LLM, etc., and may be in a Chakra trace format. As yet another nonlimiting example, the trace data 124 may be generated synthetically using reference traces along with the trace generation tool.

In some embodiments, the simulator selector module 130 may receive a configuration data 132, a hardware data 154 (specific hardware capabilities), and/or the trace data 124. The simulator selector module 130 may select one or more simulators from simulators 110 based on the received information. For illustration purposes it is presumed that the simulator selector module 130 selects the simulator 112 from the simulators 110. In one nonlimiting example, the simulators 110 may be one or more Astra-Sim (scalable system-level simulation framework designed to model and study distributed deep learning (DL) training at datacenter and supercomputer scale to model computation behavior (e.g., how neural network layer executes), model communication patterns (e.g., gradient all-reduce, parameter synchronization, etc.), and model network topology and hardware interconnects (e.g., Ethernet, InfiniBand, NVLink, custom fabrics, etc.), HTSim (high-performance discrete event network simulator to model transport protocols (e.g., TCP, multipath TCP, congestion control mechanisms, etc.) and/or analyze network congestion/flow scheduling/transport behavior under different loads/topologies), NS3 (network simulator 3 used to model/simulate/analyze computer networks from wired and wireless systems to complex internet-scale architectures), GNS3 (network emulation tool to design/configure/test real network topologies virtually using networking software images), Analyzers (e.g., average GPU utilization of an individual GPU or all GPUs in the system and may further include statistical information, e.g., clock speed, cycles per instructions, instructions per cycle, instructions per second, millions of instructions per seconds (MIPS) or floating point operations per second (FLOPS), pipeline depth/width, branch prediction accuracy, cache hit/miss rates, cache latency, thread usage, idle time, memory latency, cache bandwidth, memory bandwidth, ECC error count, etc.), Prometheus (monitoring and alerting system for collecting/storing/analyzing metrics from computer systems/applications/infrastructure in real time), InfluxDB, Grafana (data visualization and observability platform to analyze/explore/monitor metrics/logs/traces from a variety of data sources), etc. It is appreciated that one or more simulators within the simulators 110 may be a combination of two or more simulators and/or modification to one or more simulators.

In some embodiments, the configuration data 132 may define the configuration settings for the simulation via a topology specification file such as a .topo file. It is appreciated that in some embodiments, the configuration data 132 may define the physical configuration of the switches and computing nodes, in a data center simulation context. The configuration data 132 in the example of networking and data center simulation may provide information to the simulator 112 on the layout of the network. A nonlimiting example of a configuration data 132 is shown in FIG. 2B. It is appreciated that configuration data 132 being presented in a file, thus enabling the experiment to be repeated or modified (enable reproducibility). Providing the configuration data 132 as a file further enables the users to define complex topologies without hardcoding them into the simulator while enabling the selected simulator 112 to optimize for large-scale datacenter simulation (support scalability). Additionally, the configuration data 132 presented in a file enables one or more network designs in a .topo file to be swapped out with another, e.g., under the same traffic condition (providing flexibility in experimentation).

In the example of FIG. 2B, the configuration data 132 may define a 3-tier hierarchical network topology for the simulator 112, resembling a Fat-Tree architecture. In this nonlimiting example, 64 nodes (e.g., total number of end hosts (servers) in the network), 3 hierarchical levels (e.g., Tier 0, Tier 1, and Tier 2), and podsize of 8 where each pod is a group of switches and hosts and where each pod contains 8 nodes, are defined by the configuration data 132. The pods may be used in FatTree topologies. Tier 0 may be the edge tier (lowest tier) that is coupled to the end hosts. Tier 0 may include a downlink speed of 100 Gbps to the host operators, radix-down (e.g., number of network paths in a switch in the down direction) of 4 where each Tier 0 switch connects to 4 hosts, radix-up of 4 where each Tier 0 switch connects to 4 Tier 1 switches, and where the downlink latency is 1000 nanosecond for links to hosts. Tier 1 may be the aggregation tier that aggregates traffic from Tier 0 and connects upward to Tier 2. Tier 1 may include a downlink speed of 100 Gbps, a similar radix-down, radix-up, and downlink latency as Tier 0. Tier 1 may include a bundle 2 where each logical link between Tier 1 and 2 is composed of two physical links and bundled for higher bandwidth or redundancy. Tier 2 may be the topmost tier forming the backbone of the network. Tier 2 may have a similar downlink speed and latency as Tiers 0 and 1. Tier 2, however, may include 8 radix-down where each of the Tier 2 switches connect to 8 Tier 1 switches. Tier 2 may include no bundling and have a single physical layer. The configuration data 132 may define the rules as opposed to the exact counts of the components.

It is appreciated that hardware specific information may be provided as hardware data 154 that was absent from traditional simulators. The hardware data 154 along with the configuration data 132 may be provided from the simulator selector module 130 to the selected simulator 112. It is appreciated that the hardware data 154 may include hardware capabilities and hardware attributes for the hardware component that is being used in the simulation.

In one nonlimiting example, the hardware data 154 in the networking equipment context may be whether it supports TRILL extension that simplifies layer 2 multipath networking and replaces spanning tree protocol (STP). In another nonlimiting example, the hardware data 154 may be an Application Centric Infrastructure (ACI) that is a software-defined networking (SDN) with policy driven automation for data centers, or may be enhanced interior gateway routing protocol (EIGRP) used for proprietary routing protocol, etc. As another nonlimiting example, the hardware data 154 may be whether the hardware component supports operating system automation scripts (commit scripts, op scripts) used for deep customization of routing/switching behavior with native scripting, virtual chassis for stack multiple switches to act as one logical device with proprietary protocols, etc. As yet another nonlimiting example, the hardware data 154 may be whether the hardware system supports centralize telemetry and orchestration platform, extensible operating system (EOS) extensibility with Python application programming interfaces (APIs) for native Python software development kit (SDK) for deep automation inside switches, etc. In yet another nonlimiting example, the hardware data 154 may be whether a controller management supports proprietary software defined network (SDN) controller with AI-driven network optimization, versatile routing platform (VRP) OS features with advanced IPV6 transition protocols, etc.

The hardware data 154 in the memory context may be whether Persistent Memory (PMem) provides byte-addressable nonvolatile memory for high-performance computing and databased, or may include memory protection extension (MPE) to enhance hardware-level memory security, etc. In one nonlimiting example, the hardware data 154 in the memory context may be whether hardware management console (HMC) supports high-bandwidth proprietary interconnect for memory modules. As yet another example, the hardware data 154 in the memory context may be whether high bandwidth memory (HBM)-processing-in-memory (PIM) may be used to embed compute logic inside high-bandwidth memory modules for AI workloads. As another nonlimiting example, the hardware data 154 in the memory context may be whether the hardware components supports proprietary compression algorithms to optimize bandwidth for graphics processing units (GPUs). As yet another nonlimiting example, the hardware data 154 may be whether in-fabric memory access (IFMA) can be used for proprietary memory interconnect for processors.

The hardware data 154 in the computing context may be whether the hardware component supports specializes instructions for accelerating AI workloads, or may include vPro technology that is a hardware-based remote management for enterprise devices, or may include software guard extensions (SGX) used for secure enclaves for confidential computing, etc. The hardware data 154 in the computing context may be whether the hardware component supports secure memory encryption (SME) and/or secure encryption virtualization (SEV) for secure virtualization in the CPUs, or may include infinity fabric used for proprietary interconnect for multi-die chiplets, etc. As yet another nonlimiting example, the hardware data 154 in the computing context may be whether the CUDA cores support proprietary parallel computing platform for GPU acceleration, or whether the hardware component supports high-speed GPU-to-GPU interconnect, etc.

In some embodiments, the simulator 112 may generate a topology (as illustrated in FIG. 2C such as node connectivity, radix constraints, pod structure, etc., to satisfy the rules from the configuration data 132) based on the received information, e.g., hardware data 154, configuration data 132, workload data 122, trace data 124, etc. It is appreciated that the simulator 112 may perform simulation based on one or more of the workload data 122 and the trace data 124 using the generated topology. The generated topology may describe the structure of the simulated network such as number of nodes (hosts, switches, GPUs, etc.), interconnections between nodes, link properties such as bandwidth and latency, topology type such as FatTree, Clos, or custom layouts, etc. For example, FIG. 2C illustrates a nonlimiting example of the topology of a data center with the core/spine 210 (providing high-speed and resilient backbone interconnecting all leafs), the leaf layer 220 (also referred to as aggregation layer that enforces policy and connects servers/storage/GPUs via Top of Rack (ToR) and uplinks to spines), the ToR switches 230 (connect directly into servers and GPUs), AI clusters 240 (e.g., a number of CPUs, GPUs, etc.), and switches 250 (includes switches 251-258). It is appreciated that the number of components in the core/spine 210 layer, the number of components in the leaf layer 220, the number of switches in the ToR 230, the number of clusters in the AI clusters 240, and the number of switches 250 may be determined based on the rules set out from the configuration data 132 (as described above) and is shown here for illustrative purposes and should not be construed as limiting the scope of the embodiments.

In some embodiments, the simulation data 182 may be generated (e.g., as log files) by the simulator 112 simulating the workload data 122 on the generated topology. In one nonlimiting example, the simulation is for a Fat Tree with 200G Ethernet with 8K GPUs in a 3 Tier system, as described above. The simulator 112 may perform permutations for subscription ratio 1/4/8:1, entropy variation 1/32/64, sender/receiver based congestion control, trimming, and explicit congestion notification (ECN), as shown in FIG. 2D. The simulation data 182 generated by the simulator 112 is transmitted to the analyzer module 140 (which may be part of the simulator 112 but shown separate here for illustrative purposes). An example of the simulation data 182 is shown in FIG. 2E for illustration purposes and should not be construed as limiting the scope of the embodiments. The simulation data 182 may have a file format such as Idmap.txt, Htsim output, console log, Chakra.json, Chrome.json, Astrasim output, NS3 log, etc. It is appreciated that in the nonlimiting example of FIG. 2E, derived metrics are rendered and may include Mean packet transfer time, maximum packet transfer time, GPU usage overtime, average, median, etc. According to some embodiments, the derived metrics may be calculated using collected metrics, e.g., number of packets in transfer network, number of bytes in packet in transfer network, histograms, etc. FIG. 2E provides definitions and units (derived metric) based on the simulation data. An example of a simulation data is illustrated in FIG. 3A below. The analyzer module 140 may parse the simulation data 182, analyze the parsed data, and export the analysis (with the parsed data or subset thereof) as simulation analysis data 142 to the output device 150, e.g., a display. In one nonlimiting example, different metrics that are observed may be correlated using common timestamps and rendered as the simulation analysis data 142. In yet another nonlimiting example, temporal dependencies in a Gantt-graph may be rendered as the simulation analysis data 142. The analysis of the parsed data using the analyzer module 140 may be using easy wireshark-style filters, excel-style trace view, Quick to use graphs, Graphs-based navigation, Built-in network collective analysis, Gantt-graphs, topology visualization, statistical analytics on graphs, comparative analysis of multiple files, etc. The simulation analysis data 142 may be output from the analyzer module 140 to the output device as a comma separated value (CSV) file or Prometheus. An example of the simulation analysis data 142 is shown in FIG. 3A for illustration purposes. FIG. 3A illustrates values that are collected during simulation and used to derive the metric, as shown in FIG. 2E. It is appreciated that the simulation analysis data 142 may be one or more log files that includes parsed and extracted data, e.g., telemetry data. In FIG. 3A, the log file includes telemetry metrics from the simulation ran by the simulator 112 and may include network throughput, network packets, network bytes in flight, network packets in flight, GPU utilization percentage for GPU nodes (e.g., 64 of them here), GPU communication utilization percentage for GPU nodes, throughput recorded at each of the links in the topology (e.g., throughput between node 1 and ToR switch 1, throughput between node 1 and ToR switch 1, etc.), etc. The output device 150 may further output simulation results and analysis along with the topology of the network as generated by the simulator 112, as shown in FIG. 3B. The visual representation of the data center and various simulation values enables one to make an informed decision regarding the structure of the system, enables one to replace one hardware specific data (with a set of hardware capabilities) with another hardware specific data (with another set of hardware capabilities) and to rerun the simulation to determine whether performance is improved, enables one to modify one or more parameters associated with the system to achieve higher performance (e.g., increase utilization, reduce latency, reduce cost, reduce power, etc.).

It is appreciated that, as illustrated above, hardware specific data is used in the simulation, thereby enabling one hardware specific component to be replaced with another and for the simulation to provide additional insights into hardware specific components that can be used to optimize the performance of the system as a whole. It is appreciated that the embodiments are described with respect to hardware specific capabilities for illustrative purposes and should not be construed as limiting the scope of the embodiments. For example, hardware capabilities may also encompass hardware feature enabling certain features such as system software, protocol, fabric, etc., and/or different communication standards, e.g., Ethernet, UltraEthernetTransport, Ultra Accelerator Link (UAL), etc. The comparison of hardware specific information was traditionally ignored and the simulation was merely focused on the generic and functionality of the component as opposed to its hardware specifics capabilities. As such, a more accurate simulation is provided and additional insights may be gained into specific system configuration based on hardware capabilities, thereby enabling additional parameters to be adjusted, e.g., by replacing one hardware component in the simulation with another (e.g., by different hardware components), to improve performance. The simulation may be used to modify one or more aspect of the system, e.g., scale up, scale out, replace one hardware component with a set of hardware capabilities with different hardware component with a different set of hardware capabilities, addition/removal of nodes/components, etc., to improve performance, e.g., increase utilization, reduce latency associated with communication or processing, increase bandwidth, reduce bottleneck associated with memory access or data movement, etc.

In the above examples, simulation with respect to a data center is used for illustrative purposes and should not be construed as limiting the scope of the embodiments. As another nonlimiting example, processor and/or microarchitecture simulation may include running benchmarks on an instruction-level simulator to test execution code associated with a new processor design. In one nonlimiting example processor and/or microarchitecture simulation may include pipeline and cache simulation to study pipeline stalls, branch prediction accuracy, cache hit/miss rates to optimize CPU performance, etc. In one nonlimiting example, the processor and microarchitecture simulation may also include GPU simulation to test shader pipelines, memory bandwidth, parallel thread scheduling before fabricating hardware, etc.

Memory and/or storage simulation may include dynamic random access memory (DRAM) timing simulation to evaluate latency, throughput, fresh cycles of memory modules, etc. In one nonlimiting example, the memory and storage simulation may include solid state drive (SSD) or hard drive disk (HDD) performance models to simulate I/O requests, wear-leveling, garbage collection in flash storage, etc. As yet another nonlimiting example, the memory and storage simulation may include memory hierarchy simulation to model interaction between registers, cache (L1/L2/L3), main memory, virtual memory paging, etc.

The network and communication simulation may include interconnect simulation to test bus architectures, crossbars, NoCs for multicore processors, etc. In one nonlimiting example, the network and communication may be simulated in associated and across multiple data centers to simulate large AI workloads being processed by multiple data centers, in one training run, which requires the underlying networking between the data centers. In one nonlimiting example, the network and communication simulation may include a data center network simulation (e.g., scale up, scale out, scale across, etc.) for modeling handling of traffic by the servers and switches under load. As yet another nonlimiting example, the network and communication simulation may include high-speed input/output (I/O) simulations such as peripheral component interconnect express (PCIe), universal serial bus (USB), Ethernet link-layer simulations, etc., to evaluate throughput and latency.

The system level simulations may include operating system kernel simulation to explore scheduling, memory allocation, process management under synthetic workloads, etc. The system level simulations in one nonlimiting example may include virtual machine and hypervisor simulation to test virtualization overhead and multi-operating system (OS) hosting performance. In one nonlimiting example, the system level simulation may include cloud infrastructure simulation for modeling virtualized compute, storage, and/or network allocation in the cloud environment. In yet another nonlimiting example, the system level simulation may include GPU kernel simulators used to accurately run GPU instructions for both computation and communication kernels and memory access patterns.

The thermal and power simulations in one nonlimiting example may include thermal modeling of a processing component, e.g., central processing unit (CPU) or GPU, to predict heat generation under different workloads and validating cooling solutions. In one nonlimiting example, the thermal and power simulations may include power consumption simulation to evaluate dynamic voltage and/or frequency scaling (DVFS) policies to reduce energy use. As yet another nonlimiting example, the thermal and power simulations may include battery and power supply simulation to test UPS power system handing different workloads or failures.

The reliability and fault tolerance simulations in one nonlimiting example may include error injection simulation to analyze hardware performance to faults such as bit flips, stuck-at faults, fault tolerance in a network (link connections between two or more switches or between a switch and a node going down or degrading), and testing error correction codes (ECC). In one nonlimiting example, the reliability and fault tolerance simulation in one nonlimiting example may include aging and wear out models to predict lifetime degradation of transistors and storage cells. As yet another nonlimiting example, the reliability and fault tolerance simulations may include resilience testing to simulate power failures, network interruptions disk crashes to validate recovery strategies, etc.

The modular and specific hardware simulation provided by the new simulation network, as described above, enables additional insights to be gained, e.g., specific system configuration based on different hardware capabilities. Comprehensive comparison between different hardware components based on their hardware capabilities offers additional insight to optimize the system at scale. In other words, the simulation environment, as described above, provides a modular and hardware specific simulation environment where components (e.g., hardware components) with a set of hardware capabilities can be replaced with another set of hardware components with a different set of hardware capabilities and the performance of the system can be simulated based on the changes. It is appreciated that the simulation network, as described above, may be used to capture additional data, e.g., logfiles, intermediate data, etc., which can subsequently be used to train and to be used in an agentic AI.

It is appreciated that the agentic AI may be used (once trained and once having access to the simulation data) to autonomously and proactively change one or more aspect of the system being simulated intelligently to improve performance, e.g., increase utilization, reduce latency, power, total cost of ownership (TCO), etc., by improving while reducing cost until the system is optimized. In one nonlimiting example, the agentic AI may be utilized to produce key performance index (KPI) such as TCO and power associated with the system being simulated. The simulation environment, as described above, may enable trace driven simulations of distributed AI training and/or inference workloads at scale, e.g., at data centers. As such, software and hardware can be codesigned in existing infrastructures, e.g., data centers, or future infrastructures, e.g., data centers, in an optimum fashion. An agentic AI may be used to autonomously perform a number of different simulations, as described above, and to modify one or more parameters (e.g., replacing one hardware component with a first set of capabilities with a hardware component with a second set of capabilities, changing parameters of one or more components in the system, replacing one hardware component with a certain capabilities and KPI with another hardware component with a different set of capabilities and KPI, etc.) of the system intelligently to optimize performance. It is appreciated that one or more application programming interfaces (APIs) commands may provide abstractions, interfaces, and actions to integrate the one or more agentic AIs into the proposed simulation environment.

It is appreciated that the simulation environment, as described above, may utilize extensive logging and unified data warehousing to capture insights that are used for training/retraining of the one or more agentic AIs. In one nonlimiting example, data, e.g., log files, may be created and captured through various means, e.g., encapsulating the data into the one or more API calls, capturing debug or intermediate outputs from one or more AI models within the simulation environment, code modification to one or more software modules, models and framework components for providing logging capabilities, etc. In one nonlimiting example, the simulation associated with the simulation environment may include capturing traces, executing simulation runs, analyzing the simulation outputs, and creating a final report that are captured as hierarchical logs and links to associated input/output data. The one or more agentic AI may autonomously and intelligently optimize one or more configuration (hardware, software, etc.) associated with the system and rerun the simulation and repeat this process a number of times in order to optimize the performance of the system.

In one nonlimiting example, an agentic AI may be integrated into the simulation environment, as described above, as a tool for managing and accounting of configuration, projection models, inputs, trace files, outputs, and analysis, to name a few. Agentic AI is adaptive and learns based on the simulation results (current and prior results) and analysis tool. For example, an agentic AI may change default parameters and configuration settings (by using a larger or smaller search space than initially defined when optimizing the system configuration). As another example, the agentic AI may create synthetic workloads derived from archived workloads using an AI/ML process such as clustering. In one nonlimiting example, the agentic AI may adapt based on user feedback. Agentic AI may autonomously make decisions associated with changing the simulation flow and/or scope based on prior observations, e.g., identifying that scaling out a workload to larger node count is not beneficial and as a result stops the sweep across node counts that are larger than the identified threshold. In yet another example, the agent AI may autonomously conduct experiments (by running simulations) that may result in a new optimal system configuration that may be different from the proposed system configuration (by the user) with reasoning explaining the rationale, thereby allowing the user to make an informed decision on whether to change the configuration.

In some embodiments, multiple agentic AIs may be used instead of a single agent in order to enable customized agentic AI to be used for each specific aspect of the system, thereby resulting in a better optimization and performance. For example, agentic AIs may utilize real-time data from InfluxDB (opensource, NoSQL time-series database designed for high-performance storage and retrieval of time-stamped data suited for application and infrastructure monitoring, Internet of Things (IoT) sensors, and real time analytics) queries to decide on pre-emptive halting of simulations if anomalies occur and to optimize configurations for subsequent runs in a timely fashion. Using multiple specific agentic AIs also enables each agentic AI to be modified with a newer version and replaced, as needed, which supports long-term deployment and maintainability.

According to some embodiments, one or more agentic Als may be used to re-run experiments continuously (rerunning simulations), optimizing configuration parameters until optimal result is reached without human intervention. As such, the simulation environment using agentic Als allows for mapping of existing flows to automation to start and to evolve over time to increase capabilities and/or optimize the flow.

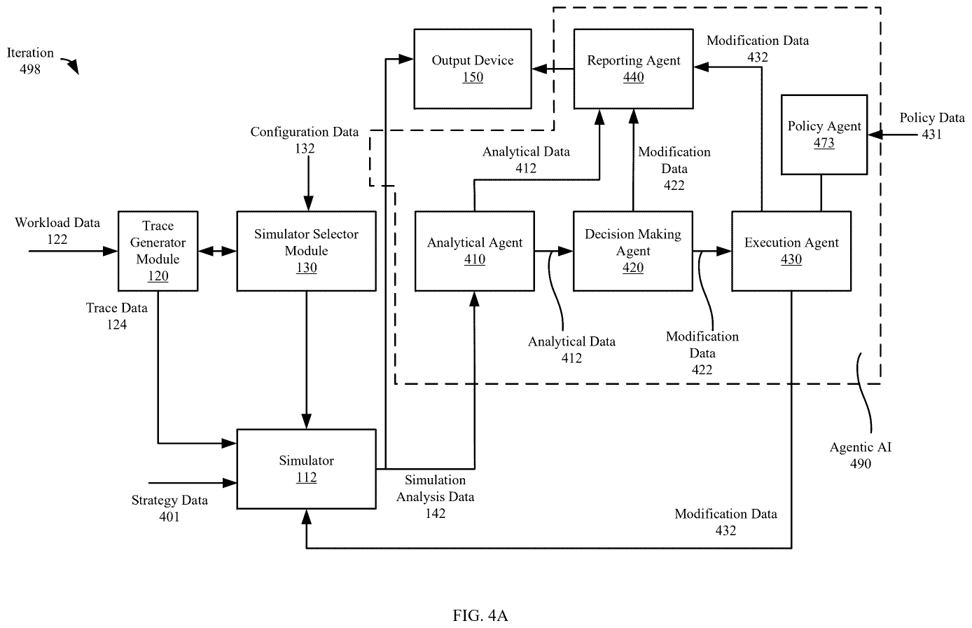

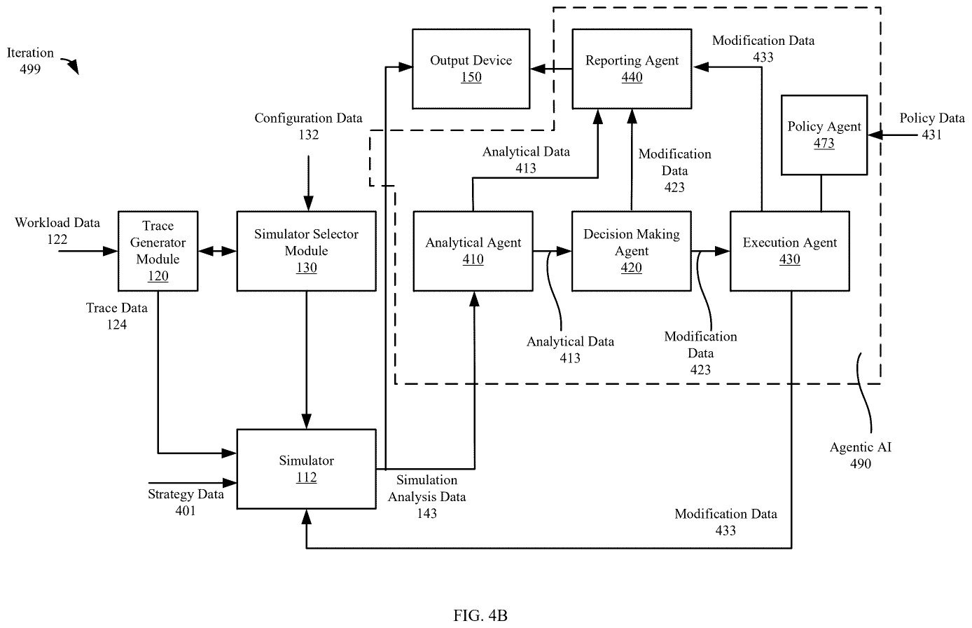

Referring now to FIG. 4A, a simulation environment with agentic AI during one simulation iteration 498 to optimize performance according to one aspect of the present embodiments. FIG. 4A is similar to that of FIG. 1 with the addition of an agentic AI 490 module to the output from the simulator 112. According to one nonlimiting example, the simulator 112 may also receive a strategy data 401, e.g., limiting maximum power consumption of GPUs even if that results in lowering performance. It is appreciated that in this example, the analyzer module 140 is integrated within the simulator 112 and the output from the simulator is the simulation analysis data from the analyzer module. In this nonlimiting example, the hardware data 154 is provided as part of the configuration data 132. Similar to FIG. 1, it is presumed that simulator 112 is selected, by the simulator selector module 130, from simulators 110 (not shown here for brevity). The simulator 112 (that includes the analyzer module 140) generates simulation analysis data 142, as described above. The simulation analysis data 142 may be transmitted to the agentic AI 490. In some embodiments, the simulation analysis data 142 may include telemetry data, raw data (CSV), live InfluxDB data through Telegraf collector, etc.

The agentic AI 490 is configured to analyze the simulation analysis data 142 that may include telemetry data to correlate simulation configuration and performance (correlating current simulation run to prior simulation runs from the past and from the memory repository), extract actionable insight from the data, and further to identify bottlenecks/anomalies such as under-utilization, resource imbalance, increase latency, low bandwidth, etc. In one nonlimiting example, the agentic AI 490 may generate statistical data from the analyzed data. In one nonlimiting example, the agentic AI 490 may also analyze and process meta data to gain further insights into the simulation results and may generate a summary of the findings, e.g., anomalies, etc. It is appreciated that the agentic AI 490 may use the actionable insight, the identification of bottlenecks/anomalies, the correlation of the simulation configuration and performance, etc., and based on historical trend (or previously generated models) generate one or more recommendations, e.g., configuration settings, swapping one hardware component with another hardware component with different hardware capabilities, change to a topology, scale out (increasing the number of components) and/or scale up (increasing the capabilities of the underlying components) and/or scale across (multiple data centers to work in conjunction with one another for example to run a single training run) recommendation, etc.

It is appreciated that the agentic AI 490 may optimize strategies, e.g., optimize GPU utilization, improve network latency, improve network throughput, improve network topology, etc., based on the extracted actionable insight and/or identification of bottlenecks/anomalies, etc. According to some embodiments, the agentic AI 490 may identify a subset of parameter space based on the optimization strategy to focus on and may balance exploration versus exploitation in the optimization process. In other words, a subset of parameters that may directly impact the strategy are used and other parameters are ignored (by having little to no impact). As one nonlimiting example, to reduce network latency a subset of parameters such as topology, link bandwidth, link latency, buffer size, etc., may be identified while other parameters may be ignored. In one nonlimiting example and in the data center context, the agentic AI 490 may form a new topology parameter recommendation. It is appreciated that the agentic AI 490 may execute based on the optimization and the recommendation. The agentic AI 490 may ensure that the recommendation and the optimized plan does not violate a system limitation For example, if a switch support only 8 ports for connection to NIC, where each NIC is connected to a GPU and where there are 2 such switches in the system. This configuration allows 2*8 GPUs to be connected. However, if the agentic AI 490 determines that only 9 GPUs are needed and a single switch is sufficient, this would violate the system limitation as a switch can only support 8 GPUs. As such, even with 9 GPUs, 2 switches are needed. The agentic AI 490 may autonomously use the recommended configuration parameters and recreate the configuration data 132 (file) based on the recommendation and optimized plan. The agentic AI 490 may further ensure syntactic correctness of the topology and configuration as well as applying and validating domain-specific constraints of the topology and other configurations.

In some embodiments, the agentic AI 490 may output modification data 432 such as a file, e.g., in .topo format, system.json, etc., to the simulator 112 to enable a new simulation to be run based on the modification, e.g., new topology, hardware components with different hardware capabilities, new topology parameter, scaling out (increasing/decreasing the size and number of nodes), scaling up (increasing/reducing the resources such as GPU/GPU/NICs/etc. in the scale up domain), scale across, configuration hardware with different parameters, etc. In one nonlimiting example, the agentic AI 490 may output modification data 432 to indicate the manner by which the simulator should decompose a given collective into send/receive messages (e.g., ring, double binary tree, halving doubling, etc.). As such, the simulator 112 may rerun a simulation based on the modification data 432. It is appreciated that modification data 432 may include modification to trace data 124, modification to workload data 122, modification to the configuration data 132 (that may include the hardware data 154, etc. In one nonlimiting example, the agentic AI 490 may determine that the number of GPUs to be used may be reduced due to underutilization and observing idle time or that the parallelization strategy may be applied to the workload to change the distribution of workload to fewer GPUs and to increase their utilization. It is appreciated that the trace data may be modified based on the determination by the agentic AI 490. As yet another nonlimiting example, the agentic AI 490 may determine that more switches and/or radixes to the switches should be added to increase throughput. It is also appreciated that the modification data 432 may be sent to a simulator different from simulator 112 to gain further insights. For example, the modification data 432 may be sent to simulator 117 to gain further insights that can be used to further provide a more suitable recommendation and to optimize the system.

It is appreciated that in some embodiments, the agentic AI 490 may also generate a summary and report of the insights, the recommendations, the reason for the recommendations, the optimization, etc. The generated summary and report may be rendered to a user via the output device 150. It is appreciated that the agentic AI 490 may tailor the summary and report in different granularity levels based on the target audience, e.g., customers, business leaders, technical versus nontechnical individuals, etc. It is appreciated that the meta data associated with the operations of the agentic AI 490, as described above, may also be generated and saved for debugging and quality assurance at a later stage.

It is appreciated that a single agentic AI performing many different functions may be slow to respond given the large model being used as well as not performing as well as a customized agentic AI for each function. Replacing a single agentic AI with multiple agents increases efficiency, traceability and reliability. Additionally, leveraging multiple agents enables multiple agents to operate in parallel (multitasking) where the agents may mapped to different compute servers. Accordingly, multiple agentic AIs, e.g., analytical agent 410, decision making agent 420, execution agent 430, reporting agent 440, etc., may be used instead of a single agentic AI 490 in order to enable customized agentic AI to be used for each specific aspect of the system, thereby resulting in a better optimization and performance. It is appreciated that each agent has a specific function and may operate independently of the other agents using tools such as LLM or APIs. The agents, e.g., analytical agent 410, decision making agent 420, execution agent 430, reporting agent 440, etc., lean by interacting with the environment (e.g., simulation environment), updating memory, adapting strategies, and/or user feedback, as opposed to retraining LLMs.

In one nonlimiting example, the analytical agent 410 receives the simulation analysis data 142 from the simulator 112. It is appreciated that the simulation analysis data 142 may include telemetry data, raw data, live InfluxDB data through telegraf collector, etc. The analytical agent 410 is configured to analyze the simulation analysis data 142 that may include telemetry data in order to correlate simulation configuration and performance (correlating current simulation run to prior simulation runs from the past and from the memory repository), extract actionable insight from the data, and further to identify bottlenecks/anomalies such as under-utilization, resource imbalance, increase latency, low bandwidth, etc. In one nonlimiting example, the analytical agent 410 may generate statistical data from the analyzed data. In one nonlimiting example, the analytical agent 410 may also analyze and process meta data to gain further insights into the simulation results and may generate a summary of the findings, e.g., anomalies, etc. The analytical agent 410 generates analytical data 412 based on its analysis, which is transmitted to the decision making agent 420.

It is appreciated that the decision making agent 420 may receive the analytical data 412 and use the actionable insight, the identification of bottlenecks/anomalies, the correlation of the simulation configuration and performance, etc., and based on historical trend (or previously generated recommendations, e.g., configuration settings, swapping one hardware component with one set of hardware capabilities with another hardware component with a different set of hardware capabilities, change to a topology, scale out and/or scale up recommendation, etc. It is appreciated that the decision making agent 420 may optimize strategies (e.g., reducing power consumption, increasing throughput, etc.) based on the extracted actionable insight and/or identification of bottlenecks/anomalies, etc. According to some embodiments, the decision making agent 420 may identify a subset of parameter space to focus on and may balance exploration versus exploitation in the optimization process. In one nonlimiting example and in the data center context, the decision making agent 420 may form a new topology parameter recommendation. The decision making agent 420 may generate modification data 422 that reflects the decision on possible modifications to be made to the system.

It is appreciated that the execution agent 430 receive the modification data 422 and may execute based on the optimization and the recommendation. The execution agent 430 may ensure that the recommendation and the optimized plan does not violate a system limitation. For example, the execution agent 430 may be in communication with a policy agent 473 that receives policy data 431. The policy agent 473 ensures that the execution agent 430 executes the recommendation and optimized plan, as provided by the decision making agent 420, without violation of a policy (e.g., based on the policy data 431). For example, if a switch support only 8 ports for connection to NIC, where each NIC is connected to a GPU and where there are 2 such switches in the system. This configuration allows 2*8 GPUs to be connected. However, if the agentic AI 490 determines that only 9 GPUs are needed and a single switch is sufficient, this would violate the system limitation as a switch can only support 8 GPUs. As such, even with 9 GPUs, 2 switches are needed. The execution agent 430 may autonomously use the recommended configuration parameters and recreate the configuration data 132 (file) based on the recommendation and optimized plan. The execution agent 430 may further ensure syntactic correctness of the topology and configuration as well as applying and validating domain-specific constraints of the topology and other configurations.

In some embodiments, the execution agent 430 may output modification data 432 such as a file, e.g., in .topo format, system.json, etc., to the simulator 112 to enable a new simulation to be run based on the modification, e.g., new topology, hardware with different hardware capabilities, new topology parameter, scaling out, scaling up, configuration hardware with different parameters, etc. As such, the simulator 112 may rerun a simulation based on the modification data 432. It is appreciated that modification data 432 may include modification to trace data 124, modification to workload data 122, modification to the configuration data 132 (that may include the hardware data 154, etc. It is also appreciated that the modification data 432 may be sent to a simulator different from simulator 112 to gain further insights. For example, the modification data 432 may be sent to simulator 117 to gain further insights that can be used to further provide a more suitable recommendation and to optimize the system.

It is appreciated that in some embodiments, the reporting agent 440 may also be used to generate a summary and report associated with the analytical agent 410, the decision making agent 420, and/or the execution agent 430. The reporting agent 440 may receive the analytical data 412, the modification data 422, and the modification data 432 and may generate a summary and report of the insights, the recommendations, the reason for the recommendations, the optimization, etc. The generated summary and report may be rendered to a user via the output device 150. It is appreciated that the reporting agent 440 may output data to the output device 150 that may be human readable, machine readable, etc. The generated summary may take different forms and may include interactive web-browser, pdf document, etc. In yet one nonlimiting example, the generated summary may include a graphical representation, visualizations and animations, etc. It is appreciated that the reporting agent 440 may tailor the summary and report in different granularity levels based on the target audience, e.g., customers, business leaders, technical versus nontechnical individuals, etc. It is appreciated that the meta data associated with the operations of the analytical agent 410, the decision making agent 420, the execution agent 430, and the reporting agent 440, as described above, may also be generated and saved for debugging and quality assurance at a later stage. It is appreciated that the output device 150 may be a display to render the data. In yet another nonlimiting example, the output device 150 may be a memory component for storing the data received from the reporting agent 440 for subsequent access and rendition, e.g., interactively rendering it on a display device.

Referring now to FIG. 4B an example of a simulation environment with agentic AI during another simulation iteration 499 to optimize performance according to one aspect of the present embodiments. In this nonlimiting example, the modification data 432 is received by the simulator 112, as described with respect to FIG. 4A. The simulator 112 may run another simulation based on the modification data 432. Accordingly, simulation analysis data 143 may be generated. The simulation analysis data 143 may be transmitted to the analytical agent 410 that generates the analytical data 413. The analytical data 413 may be transmitted to the decision making agent 420 to decide on the proper strategy and modifications to be made, thereby generating modification data 423. The modification data 423 may be subsequently transmitted to the execution agent 430 to generate a modification data 433 using the policy data 431. The modification data 433 may be transmitted to the simulator 112 to rerun the simulation based on further modification. It is appreciated that at each iteration, the performance may be compared to prior iterations and the system may be optimized accordingly. It is appreciated that the reporting agent 440 may receive the generated information from other agents in order to generate a summary and to report the findings by rendering it on the output device 150.

It is appreciated that the iteration process may continue a number of times until the system is satisfactorily optimized. It is also appreciated that the optimization during each iteration is performed intelligently by the agentic AI and with minimal manual interaction by the user. In one nonlimiting example, the agentic AI may pre-emptively halt the simulation if anomalies occur and/or to optimize configurations for subsequent runs in a timely fashion.

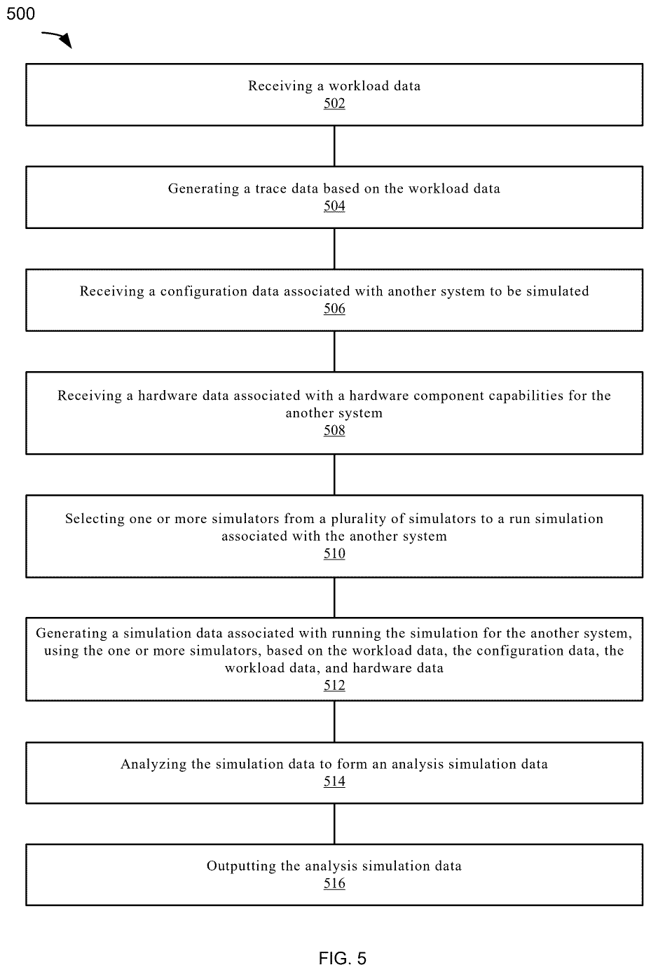

FIG. 5 depicts an illustrative flow diagram to support simulation environment based on hardware capabilities for specific hardware component according to one aspect of the present embodiments. At step 502 a workload data is received, as described above in FIGS. 1-4B. At step 504, a trace data is generated based on the workload data, as described above. At step 506, a configuration data associated with another system to be simulated is received, as described in FIGS. 1-4B. At step 508, a hardware data associated with a hardware component capabilities for a specific hardware component for the another system is received, as described in FIGS. 1-4B. At step 510, one or more simulators is selected from a plurality of simulators to a run simulation associated with the another system, as described above. At step 512, a simulation data associated with running the simulation for the another system is generated, using the one or more simulators, based on the workload data, the configuration data, the workload data, and hardware data, as described in FIGS. 1-4B. At step 514, the simulation data is analyzed to form an analysis simulation data, as described above. At step 516, the analysis simulation data is output, e.g., rendered, as described in FIGS. 1-4B.

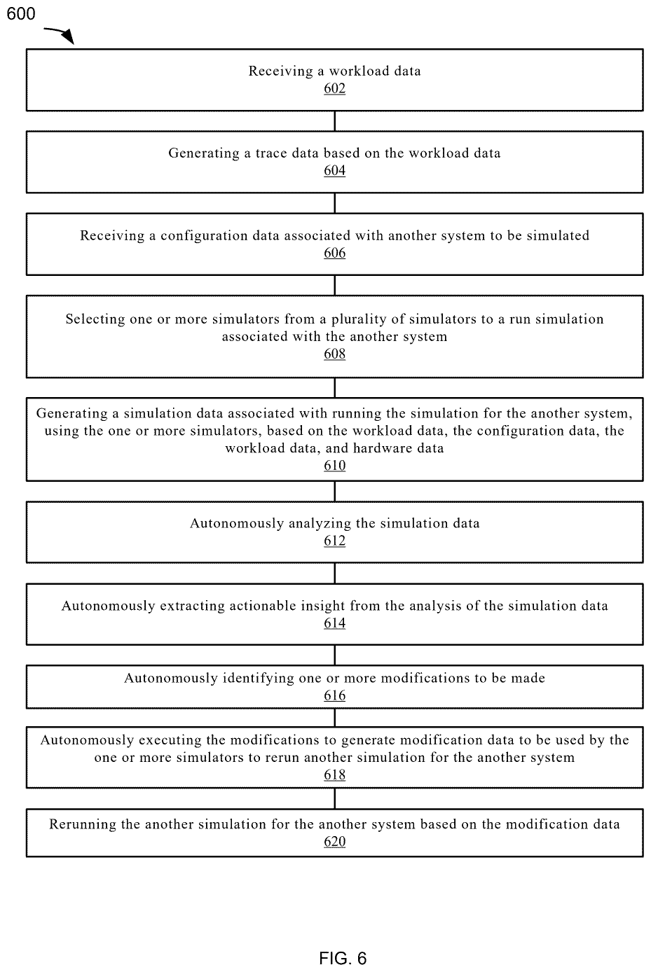

FIG. 6 depicts an illustrative flow diagram to support simulation environment coupled with an agentic AI according to one aspect of the present embodiments. At step 602, a workload data is received, as described in FIGS. 1-4B. At step 604, a trace data is generated based on the workload data, as described in FIGS. 1-4B. At step 606, a configuration data associated with another system to be simulated is received, as described above. At step 608, one or more simulators is selected from a plurality of simulators to a run simulation associated with the another system, as described in FIGS. 1-4B. At step 610, a simulation data associated with running the simulation for the another system is generated, using the one or more simulators, based on the workload data, the configuration data, the workload data, and hardware data, as described in FIGS. 1-4B. At step 612, the simulation data is autonomously analyzed, as described in FIGS. 1-4B. At step 614, actionable insight from the analysis of the simulation data is autonomously extracted, as described in FIGS. 1-4B. At step 616, one or more modifications to be made are autonomously identified, as described in FIGS. 1-4B. At step 618, the modifications are autonomously executed to generate modification data to be used by the one or more simulators to rerun another simulation for the another system, as described in FIGS. 1-4B. At step 620, the another simulation is rerun for the another system based on the modification data, as described above.

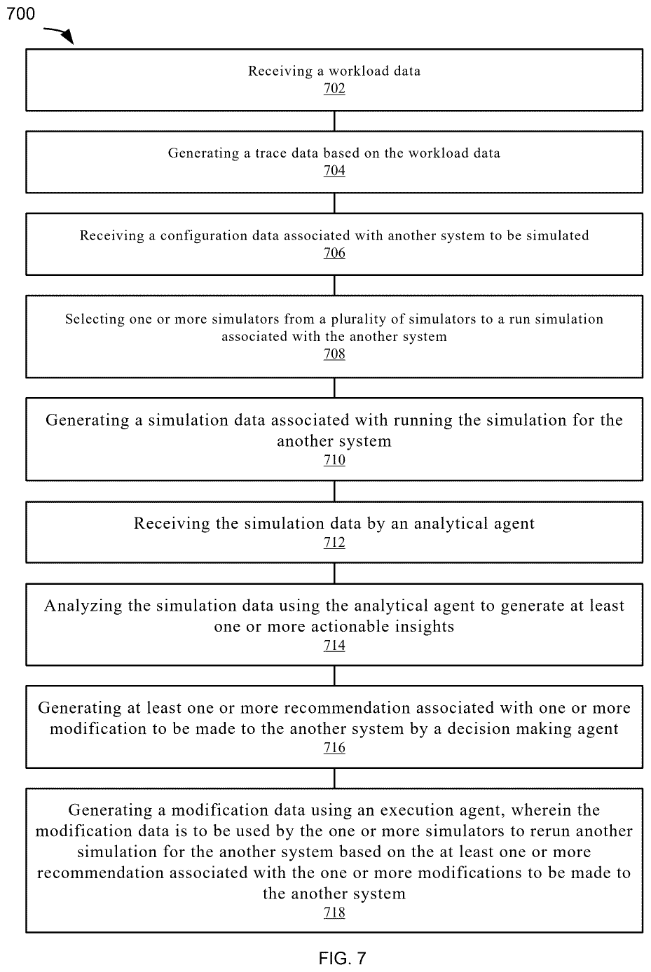

FIG. 7 depicts an illustrative flow diagram to support simulation environment coupled with a plurality of agentic Als according to one aspect of the present embodiments. At step 702, a workload data is received, as described in FIGS. 1-4B. At step 704, a trace data is generated, as described in FIGS. 1-4B. At step 706, configuration data associated with another system to be simulated is received, as described in FIGS. 1-4B. At step 708, one or more simulators is selected from a plurality of simulators to a run simulation associated with the another system, as described in FIGS. 1-4B. At step 710, a simulation data associated with running the simulation for the another system is generated, as described in FIGS. 1-4B. At step 712, the simulation data is received by an analytical agent, as described in FIGS. 1-4B. At step 714, the simulation data is analyzed using the analytical agent to generate at least one or more actionable insights, as described in FIGS. 1-4B. At step 716, at least one or more recommendation associated with one or more modification to be made to the another system is generated by a decision making agent, as described in FIGS. 1-4B. At step 718, a modification data is generated using an execution agent, wherein the modification data is to be used by the one or more simulators to rerun another simulation for the another system based on the at least one or more recommendation associated with the one or more modifications to be made to the another system, as described in FIGS. 1-4B. The analytical agent, the decision making agent, and the execution agent are independent from one another and operate independent from one another. The one or more simulators is configured to rerun the another simulation for the another system based on the modification data.

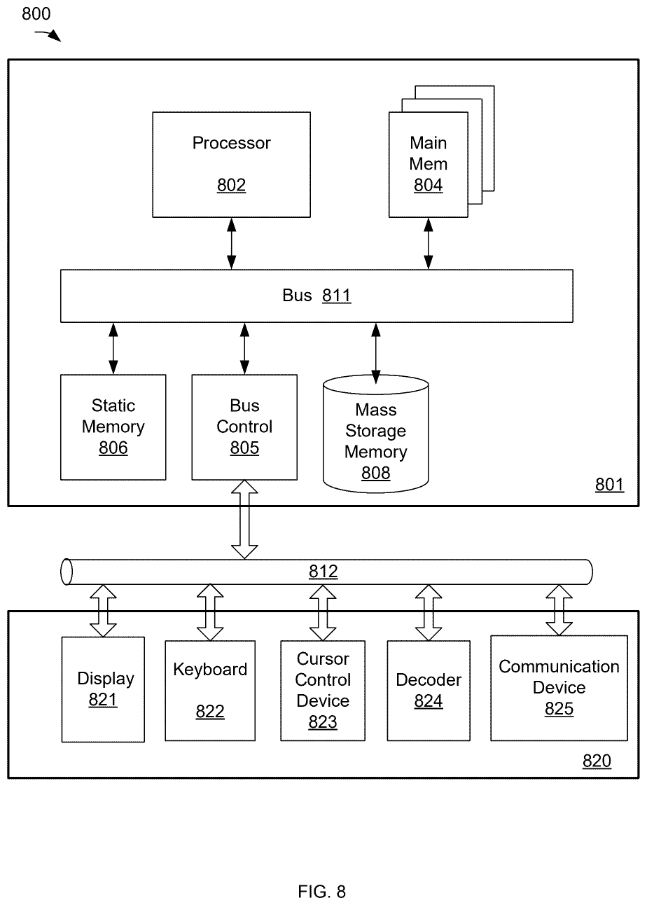

FIG. 8 is a block diagram illustrating an example of a computing system/device used to implement the system to support a simulation environment and/or agentic AI according to one aspect of the present embodiments. FIG. 8 shows simulation being performed by a computing system for illustrative purposes but it is appreciated that it may be supported by a distributed system across multiple servers. In the example of FIG. 8, the system 800 includes a processing unit 801, an interface bus 812, and an input/output (“IO”) unit 820. Processing unit 801 includes a processor 802, main memory 804, system bus 811, static memory device 806, bus control unit 805, and mass storage memory 808. Bus 811 is used to transmit information between various components and processor 802 for data processing. Processor 802 may be any of a wide variety of general-purpose processors, embedded processors, or microprocessors such as ARM® embedded processors, Intel® Core™2 Duo, Core™2 Quad, Xeon®, Pentium™ microprocessor, AMD® family processors, MIPS® embedded processors, RISC-V, or Power PC™ microprocessor.

Main memory 804, which may include multiple levels of cache memories, stores frequently used data and instructions. Main memory 804 may be RAM (random access memory), MRAM (magnetic RAM), or flash memory. Static memory 806 may be a ROM (read-only memory), which is coupled to bus 811, for storing static information and/or instructions. Bus control unit 805 is coupled to buses 811-812 and controls which component, such as main memory 804 or processor 802, can use the bus. Mass storage memory 808 may be a magnetic disk, solid-state drive (“SSD”), optical disk, hard disk drive, floppy disk, CD-ROM, and/or flash memories for storing large amounts of data.

I/O unit 820, in one example, includes a display 821, keyboard 822, cursor control device 823, decoder 824, and communication device 825. Display device 821 may be a liquid crystal device, flat panel monitor, cathode ray tube (“CRT”), touch-screen display, or other suitable display device. Display 821 projects or displays graphical images or windows. Keyboard 822 can be a conventional alphanumeric input device for communicating information between computer system 800 and computer operators. Another type of user input device is cursor control device 823, such as a mouse, touch mouse, trackball, or other type of cursor for communicating information between system 800 and users.

Communication device 825 is coupled to bus 812 for accessing information from remote computers or servers through wide-area network. Communication device 825 may include a modem, a router, or a network interface device, or other similar devices that facilitate communication between computer 800 and the network. In one aspect, communication device 825 is configured to perform wireless functions.

The foregoing description of various embodiments of the claimed subject matter has been provided for the purposes of illustration and description. It is not intended to be exhaustive or to limit the claimed subject matter to the precise forms disclosed. Many modifications and variations will be apparent to the practitioner skilled in the art. Embodiments were chosen and described in order to best describe the principles of the invention and its practical application, thereby enabling others skilled in the relevant art to understand the claimed subject matter, the various embodiments and the various modifications that are suited to the particular use contemplated.

What is claimed is:

1. A system, comprising:
a trace generator module configured to receive a workload data and generate a trace data;
a plurality of simulators;
a simulator selector module configured to
receive configuration data associated with another system to be simulated; and
select one or more simulators from the plurality of simulators to a run simulation associated with the another system, wherein the one or more selected simulators is configured to generate a simulation data associated with running the simulation for the another system; and
an agentic artificial intelligence (AI) module comprising:
an analytical agent configured to receive the simulation data and further configure to analyze the simulation data to generate at least one or more actionable insights; and
a decision making agent configured to receive the at least one or more actionable insights to generate at least one or more recommendation associated with one or more modification to be made to the another system.

2. The system of claim 1, wherein the agentic AI further comprises:
an execution agent configured to generate a modification data to be used by the one or more simulators to rerun another simulation for the another system based on the at least one or more recommendation associated with the one or more modifications to be made to the another system, wherein the analytical agent, the decision making agent, and the execution agent are independent from one another and operate independent from one another.

3. The system of claim 2 further comprising an output device configured to render at least one or more of the simulation data, actionable insight, and the one or more modifications.

4. The system of claim 1, wherein the analytical agent is configured to correlate simulation configuration and performance by comparing the simulation to prior simulation runs and past performances.

5. The system of claim 1, wherein the analytical agent is configured to identify a bottleneck or an anomaly.

6. The system of claim 4, wherein the bottleneck or the anomaly includes resource under-utilization, resource imbalance, increase in latency, or reduction in bandwidth.

7. The system of claim 1, wherein the decision making agent is configured to generate the at least one or more recommendations associated with configuration setting, topology, scale up, scale out, or a hardware component with specific capabilities for the another system.

8. The system of claim 1, wherein the decision making agent is further configured to optimize strategies based on the actionable insight.

9. The system of claim 1, wherein the agentic AI further comprises:
an execution agent configured to generate a modification data to be used by the one or more simulators to rerun another simulation for the another system based on the at least one or more recommendation associated with the one or more modifications to be made to the another system; and
a policy agent in communication with the execution agent, wherein the policy agent is configured to receive a policy data,
wherein the execution engine is configured to make changes based on the at least one or more recommendation and wherein the policy agent is configured to ensure correctness of changes being made by the execution agent.

10. The system of claim 1, wherein the agentic AI further comprises an execution agent configured to generate a modification data to be used by the one or more simulators to rerun another simulation for the another system based on the at least one or more recommendation associated with the one or more modifications to be made to the another system, wherein the execution agent is configured to generate another configuration data based on the one or modifications to be used by the one or more simulators to rerun the simulation.

11. The system of claim 10, wherein the agentic AI further comprises a reporting agent configured to receive data from the analytical agent, the decision making agent, and the execution agent, and wherein the reporting agent is configured to generate a summary of the simulation and at least one or more of the at least one or more actionable insights, the at least one or more recommendation, and the modification data.

12. The system of claim 1, wherein the one or more simulators is configured to rerun the another simulation for the another system based on the modification data.

13. A method comprising:
receiving a workload data;
generating a trace data;
receiving configuration data associated with another system to be simulated;
selecting one or more simulators from a plurality of simulators to a run simulation associated with the another system;
generating a simulation data associated with running the simulation for the another system;
receiving the simulation data by an analytical agent;
analyzing the simulation data using the analytical agent to generate at least one or more actionable insights;
generating at least one or more recommendation associated with one or more modification to be made to the another system by a decision making agent;
generating a modification data using an execution agent, wherein the modification data is to be used by the one or more simulators to rerun another simulation for the another system based on the at least one or more recommendation associated with the one or more modifications to be made to the another system,
wherein the analytical agent, the decision making agent, and the execution agent are independent from one another and operate independent from one another.

14. The method of claim 12 further comprising rendering at least one or more of the simulation data, actionable insight, and the one or more modifications.

15. The method of claim 12 further comprising correlating simulation configuration and performance by comparing the simulation to prior simulation runs and past performances using the analytical agent.

16. The method of claim 12 further comprising identifying a bottleneck or an anomaly using the analytical agent.

17. The method of claim 15, wherein the bottleneck or the anomaly includes resource under-utilization, resource imbalance, increase in latency, or reduction in bandwidth.

18. The method of claim 12 further comprising generating the at least one or more recommendations associated with configuration setting, topology, scale up, scale out, or a hardware component with specific capabilities for the another system using the decision making agent.

19. The method of claim 12 further comprising optimizing strategies based on the actionable insight using the decision making agent.

20. The method of claim 12 further comprising receiving a policy data by a policy agent, wherein the execution agent is configured to make changes based on the one or more modifications and wherein the policy agent is configured to ensure correctness of the changes being made by the execution agent.

21. The method of claim 12 further comprising generating another configuration data using the execution agent based on the one or modifications to be used by the one or more simulators to rerun the simulation.

22. The method of claim 12 further comprising:
receiving data from the analytical agent, the decision making agent, and the execution agent by a reporting agent;
generating a summary of the simulation and at least one or more of the at least one or more actionable insights, the at least one or more recommendation, and the modification data, by the reporting agent.

23. The method of claim 12, wherein the one or more simulators is configured to rerun the another simulation for the another system based on the modification data.

24. A system comprising:
a means for receiving a workload data;
a means for generating a trace data;
a means for receiving configuration data associated with another system to be simulated;
a means for selecting one or more simulators from a plurality of simulators to a run simulation associated with the another system;
a means for generating a simulation data associated with running the simulation for the another system;
a means for receiving the simulation data an analytical agent; and
a means for analyzing the simulation data using the analytical agent to generate at least one or more actionable insights.

25. The system of claim 24 further comprising:
a means for generating at least one or more recommendation associated with one or more modification to be made to the another system by a decision making agent;
a means for generating a modification data using an execution agent, wherein the modification data is to be used by the one or more simulators to rerun another simulation for the another system based on the at least one or more recommendation associated with the one or more modifications to be made to the another system.

26. The system of claim 25, wherein the analytical agent, the decision making agent, and the execution agent are independent from one another and operate independent from one another.

27. The system of claim 25, wherein the one or more simulators is configured to rerun the another simulation for the another system based on the modification data.
